(19) United States
(12) Patent Application Publication
(10) Pub. No.: US 2026/0156925 A1
(43) Pub. Date: Jun. 4, 2026

(54) INTEGRATED DEVICE COMPRISING A HIGH MOBILITY TRANSISTOR AND A MOSFET TRANSISTOR, AND MANUFACTURING PROCESS THEREOF

(71) Applicant: STMICROELECTRONICS INTERNATIONAL N.V., Geneva (CH)

(72) Inventor: Paolo COLPANI, Agrate Brianza (IT)

(21) Appl. No.: 19/376,101

(22) Filed: Oct. 31, 2025

(30) Foreign Application Priority Data
Nov. 29, 2024 (IT) 102024000027084

(51) Int. Cl. H10D 84/82; H10D 30/01; H10D 30/47; H10D 30/67; H10D 62/824; H10D 64/00; H10D 84/01

(52) U.S. Cl. CPC H10D 84/82; H10D 30/015; H10D 30/0314; H10D 30/475; H10D 30/6731; H10D 62/824; H10D 64/111; H10D 84/0123

(57) ABSTRACT

An integrated electronic device formed by a heterostructure field-effect transistor (HEMT) and a MOSFET transistor on a body having a heterostructure formed in at least one gallium nitride (GaN) based layer is provided. A first gate region overlies at least one GaN-based layer; a TFT region stack is arranged on at least one GaN-based layer, laterally to the first gate region. The TFT region stack is formed by a basement insulation region overlying at least one GaN-based layer, a semiconductor region overlying the basement insulation region and a gate dielectric region overlying the semiconductor layer. A second gate region overlies the gate dielectric region; and an insulating layer surrounds at least at the top and laterally the first gate region, the second gate region, and the TFT region stack and covers at least one GaN-based layer laterally to the first gate region and the TFT region stack.

### CROSS REFERENCE TO RELATED APPLICATION(S)

This application claims priority to and the benefit of Italian Patent Application Serial No. 102024000027084, filed on Nov. 29, 2024, entitled “DISPOSITIVO INTEGRATO COMPRENDENTE UN TRANSISTORE AD ELEVATA MOBILITA′ ELETTRONICA E UN TRANSISTORE MOSFET, E RELATIVO PROCESSO DI FABBRICAZIONE,” which is incorporated herein by reference in its entirety.

### TECHNICAL FIELD

The present disclosure relates to an integrated device comprising a high electron mobility transistor and a MOSFET transistor and to the manufacturing process thereof.

### BACKGROUND

As is known, High Electron Mobility Transistor (HEMT) devices, also known as Heterostructure Field Effect Transistors (HFETs), are becoming widely spread by virtue of their ability to operate at high voltages, their high breakdown voltage, and their high charge carrier mobility.

In a HEMT device, a semiconductor heterostructure (usually based on AlGaN/GaN layers) allows a so-called 2-Dimensional Electron Gas (2DEG) to be spontaneously generated in the device, thereby forming a channel path for electric charges. The spontaneous channel may be modulated by applying appropriate voltages at a gate region, on the channel path.

Thanks to the advantageous characteristics of HEMT devices, it is desirable to provide both N-channel and P-channel devices. However, it is difficult to provide P-channel GaN HEMT devices; in particular, it is difficult to integrate them with similar N-channel devices (both of normally-off or E-mode type, and of normally-on or D-mode type) and/or with circuitry components.

Current solutions in fact are based on a separate formation on an own substrate (using separate and mutually bonded dice or by removing part of the respective substrates) or forming stacks of heterogeneous layers so that the HEMT devices and the MOSFET devices are stacked vertically.

Such solutions are however complex from the manufacturing process point of view and therefore have high costs and low reliability and/or have large dimensions, not acceptable in many applications.

The aim of the present disclosure is therefore to provide an electronic device that integrates a HEMT and a MOSFET overcoming the drawbacks of the prior art.

### BRIEF SUMMARY

According to the present disclosure, an integrated device is provided. Also provided is a manufacturing process of the integrated device.

In an example embodiment an integrated circuit device is provided. The integrated electronic device, includes a heterostructure field-effect transistor (HEMT) and a MOSFET transistor and including: a body having a heterostructure including at least one gallium nitride based layer; a first gate region overlying the at least one gallium nitride based layer; a TFT region stack on the at least one gallium nitride based layer, laterally to the first gate region, the TFT region stack including a basement insulation region overlying the at least one gallium nitride based layer, a semiconductor region overlying the basement insulation region, and a gate dielectric region overlying the semiconductor layer; a second gate region overlying the gate dielectric region; an insulating layer surrounding, at least at a top and laterally, the first gate region, the second gate region, and the TFT region stack as well as covering the at least one gallium nitride based layer laterally to the first gate region and the TFT region stack; and a plurality of plug metal regions extending through the insulating layer and in electrical contact with the first gate region, the second gate region, the at least one gallium nitride based layer, and the semiconductor layer.

In various embodiments, the MOSFET transistor is a thin-film transistor (TFT) and wherein the semiconductor region accommodates a first and a second current conduction region separated by a channel portion of the semiconductor region, the channel portion underlying the second gate region.

In various embodiments, the second gate region includes a doped semiconductor region.

In various embodiments, the second gate region includes a metal region.

In various embodiments, the integrated electronic further includes a first HEMT conduction contact region, of metal, on the at least one gallium nitride based layer; a second HEMT conduction contact region, of metal, on the at least one gallium nitride based layer, the first HEMT conduction contact region and the second HEMT conduction contact region arranged on opposite sides of the first gate region; a HEMT gate contact region, of metal, in contact with the first gate region; a first TFT conduction contact region, of metal, in contact with a first current conduction region; a second TFT conduction contact region, of metal, in contact with a second current conduction region, the first TFT conduction contact region and the second TFT conduction contact region arranged on opposite sides of the second gate region; and the first HEMT conduction contact region, the second HEMT conduction contact region, the HEMT gate contact region, the first TFT conduction contact region, and the second TFT conduction contact region being formed in a same metal layer and being in direct electrical contact with a respective plug metal region of the plurality of metal contact regions.

In various embodiments, the integrated electronic device further includes a TFT gate contact region, of metal, superimposed on the second gate region and in direct electrical contact with a respective plug metal region of the plurality of plug metal regions.

In various embodiments, the integrated electronic device further includes a field-plate region, of electrically conductive material, arranged laterally to the first gate region.

In various embodiments, the field-plate region is of a same metal as a metal region of the second gate region.

In an example embodiment a process for manufacturing an integrated electronic device is provided. The process includes: forming a body having a heterostructure in at least one gallium nitride based layer; forming a first gate region overlying the at least one gallium nitride based layer; forming a TFT region stack on the at least one gallium nitride based layer, laterally to the first gate region, the TFT region stack including a basement insulation region overlying the at least one gallium nitride based layer, a semiconductor region overlying the basement insulation region, and a gate dielectric region overlying the semiconductor region; forming a second gate region overlying the gate dielectric region; forming an insulating layer surrounding, at least at a top and laterally, the first gate region, the second gate region, and the TFT region stack as well as covering the at least one gallium nitride based layer laterally to the first gate region and the TFT region stack; and forming a plurality of plug metal regions extending through the insulating layer and in electrical contact with the first gate region, the second gate region, the at least one gallium nitride based layer, and the semiconductor layer.

In various embodiments, the MOSFET transistor is a thin-film transistor (TFT), wherein forming a TFT region stack includes forming a first and a second current conduction region, separated by a channel portion of the semiconductor region, underlying the second gate region.

### BRIEF DESCRIPTION OF THE DRAWINGS

For a better understanding of the present disclosure, some embodiments thereof are now described, purely by way of non-limiting example, with reference to the attached drawings, wherein:

FIG. 1 shows a cross-section of an embodiment of the present integrated electronic device, comprising a heterostructure transistor and a thin-film MOSFET transistor;

FIGS. 2A-2M show cross-sections of the integrated electronic device of FIG. 1, in successive manufacturing steps;

FIG. 3 shows a cross-section of a different embodiment of the present integrated electronic device, comprising a heterostructure transistor and a metal-gate MOSFET transistor; and

FIGS. 4A-4F show cross-sections of the electronic device of FIG. 3, in successive manufacturing steps.

### DETAILED DESCRIPTION

The following description refers to the arrangement shown; consequently, expressions such as “above”, “below”, “upper”, “lower”, “right”, “left” relate to the accompanying Figures and are not to be interpreted in a limiting manner.

Furthermore, the dimensions of the various regions and structures are not necessarily to scale and have sometimes been exaggerated or reduced to allow for their representation and/or to facilitate understanding.

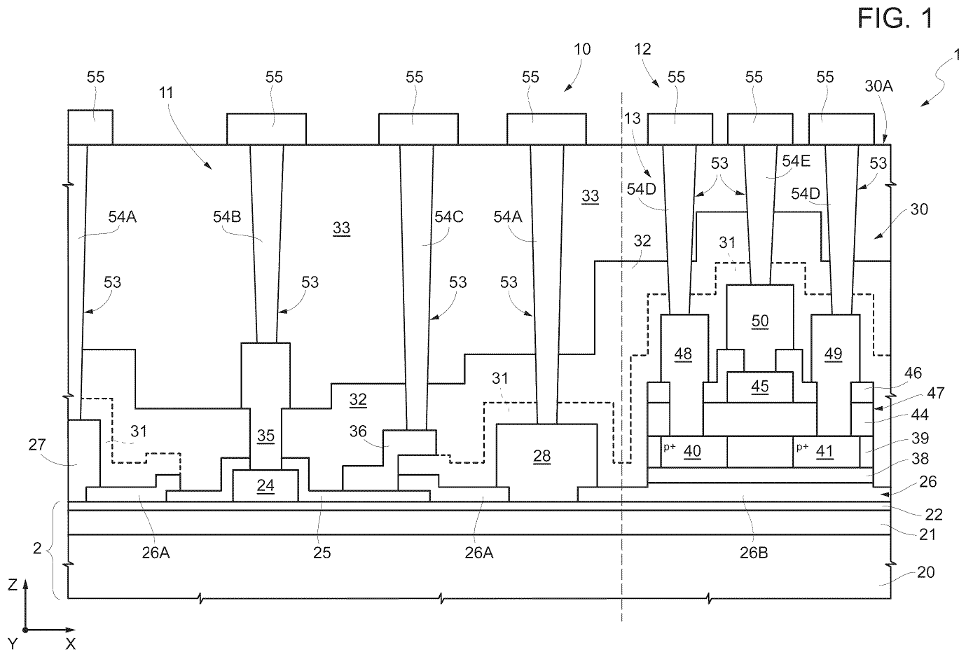

FIG. 1 shows an integrated electronic device 1 represented in an XZ section plane of a Cartesian coordinate system comprising a first horizontal axis X, a second horizontal axis Y and a vertical axis Z.

The integrated electronic device 1 comprises a first device portion 10 integrating a high electron mobility transistor (HEMT 11) and a second device portion 12 integrating a thin-film MOSFET transistor (TFT 13).

The HEMT 11 and the TFT 13 are arranged side by side, in different areas of a single die forming the integrated electronic device 1.

The integrated electronic device 1 comprises a semiconductor body 2 having a top surface 2A and comprising here a substrate 20, a first semiconductor layer 21 and a second semiconductor layer 22.

The substrate 20, shown only in part in FIG. 1, may comprise a portion of silicon and a buffer layer of gallium nitride (GaN), not represented individually.

The first semiconductor layer 21 is of a first semiconductor material, such as a first semiconductor alloy of elements of groups III and V of the periodic table; for example, the first semiconductor layer 21 may be of gallium nitride (GaN) or an alloy comprising GaN such as InGaN, in particular here of GaN. The first semiconductor layer 21 forms a channel layer of the HEMT 11.

The second semiconductor layer 22 overlies, and is in direct contact with, the first semiconductor layer 21; the second semiconductor layer 22 is of a second semiconductor material, such as a second semiconductor alloy, different from the first semiconductor alloy, of elements of groups III-V of the periodic table. For example, the second semiconductor layer 22 may be a ternary or quaternary alloy of gallium nitride, such as AlₓGa₁₋ₓN, AlInGaN, InₓGa₁₋ₓN, AlₓIn₁₋ₓAl, AlScN, in particular here of aluminum gallium nitride (AlGaN). The second semiconductor layer 22 forms a barrier layer of the HEMT transistor 13.

The first and the second semiconductor layers 21, 22 are of a first conductivity type, for example of N-type.

A HEMT gate region 24 extends on the second semiconductor layer 22, in the first device portion 10. The HEMT gate region 24 is, for example, of a third semiconductor material, such as, for example, a third semiconductor alloy of elements of groups III and V of the periodic table; in particular, the HEMT gate region 24 is here formed by P-type conductivity gallium nitride (pGaN).

The HEMT gate region 24 may have a thickness comprised between 50 nm and 200 nm, for example 100 nm.

A first sealing region 25, for example of silicon oxide, extends on the second semiconductor layer 22, on lateral surfaces and on a top surface of the HEMT gate region 25, in the first device portion 10.

The first sealing region 25 may have a thickness comprised between 30 nm and 200 nm, for example 40 nm.

An ohmic dielectric layer 26 extends on the second semiconductor layer 22, in the second device portion 12 and in part in the first device portion 10, alongside the first sealing region 25. The ohmic dielectric layer 26 may also be partially superimposed on the first sealing region 25, on the edge, in a distant position with respect to the HEMT gate region 24.

The ohmic dielectric layer 26 is for example of silicon nitride and may have a thickness comprised between 30 nm and 200 nm; for example, in the embodiment of FIG. 1, it has a thin portion 26A of about 45 nm (in the first portion 10) and a thick portion 26B (in the second portion 20) of about 70 nm.

A HEMT source contact region 27 and a HEMT drain contact region 28 extend in contact with the second semiconductor layer 22, on both sides of the HEMT gate region 24. The HEMT source 27 and HEMT drain 28 contact regions extend through the ohmic dielectric layer 26 (and may extend in part also thereon) and are of metal, for example of Ti/AlCu/TiN.

Alternatively to what shown, the HEMT source 27 and HEMT drain 28 contact regions may extend partially or completely through the second semiconductor layer 22.

A passivation layer 30 extends above the ohmic dielectric layer 26, the source and drain contacts 27, 28, the first sealing region 25, in the first portion 10, as well as above the TFT 13 (described hereinbelow), in the second portion 12.

The passivation layer 30 has a top surface 30A that represents a base surface for possible top metal interconnection layers (not shown), usable to connect the different devices (here, HEMTs and TFTs, as well as any others).

The passivation layer 30 is generally formed by a plurality of layers; in particular here it is formed by a first dielectric layer 31, for example of silicon nitride, by a second dielectric layer 32, for example of silicon oxide, and a third dielectric layer 33 (also referred to as pre-metal dielectric), for example of silicon oxide.

For instance, the first dielectric layer 31 may have a thickness comprised between 30 nm and 200 nm, for example of 70 nm; the second dielectric layer 32 may have a thickness comprised between 100 and 200 nm, for example of 150 nm; and the third dielectric layer 33 may have a thickness comprised between 400 and 800 nm, variable in the different areas of the integrated electronic device 1 since it is obtained by deposition with a high thickness and successive planarization by CMP (Chemical Mechanical Polishing) technique. The sum of the dielectrics deposited in each area of the device with respect to the level of the second semiconductor layer 22 of AlGAN may vary between 800 nm and 2000 nm.

A HEMT gate contact region 35 extends above and in contact with the HEMT gate region 24, through part of the passivation layer 30 and more precisely, here, through the second dielectric layer 32 and the first sealing region 25, in the first portion 10.

The HEMT gate contact region 35 may have a thickness comprised between 100 and 300 nm, for example 200 nm.

A field redistribution region (field-plate region 36) extends between the HEMT gate region 24 and the HEMT drain contact region 28 (moving in the direction of the first horizontal axis X), surrounded by insulating regions. In particular, here, the field-plate region 36 extends partially on the first sealing region 25 and the first dielectric layer 31, laterally to an edge of the ohmic dielectric layer 26 and of the same first dielectric layer 31, below the second dielectric layer 32.

The field-plate region 36 is of conductive material, for example of titanium nitride TiN and may have a thickness comprised between 10 nm and 150 nm, for example 85 nm.

In the second device portion 12, a basement insulation region 38 extends above the ohmic dielectric layer 26 and precisely the thick portion 26B thereof. The basement insulation region 38 is for example of silicon oxide and has a thickness comprised between 30 nm and 150 nm, for example of 50 nm.

A semiconductor region 39 extends above the basement insulation region 38. The semiconductor region 39, for example of undoped or lightly doped polycrystalline silicon to modulate the threshold of the TFT 13, is thin and has a thickness comprised between 50 nm and 200 nm, for example 100 nm.

The semiconductor region 39 accommodates a first and a second current conduction region 40, 41 of a second conductivity type, here of P-type, for example doped with boron. The current conduction regions 40, 41 are mutually spaced and form here a source region and a drain region for the TFT 13. Therefore, they are hereinafter also referred to as TFT source region 40 and TFT drain region 41.

The portion of the semiconductor region 39 arranged between the first and the second current conduction regions 40, 41 forms a channel portion 42.

A gate dielectric region 44 extends above the semiconductor region 39. The gate dielectric region 44 is, for example, of silicon oxide and has a thickness comprised between 30 nm and 150 nm, for example of 100 nm.

A TFT gate region 45 extends on the gate dielectric region 44, above the channel portion 42 in the semiconductor region 39. The TFT gate region 45 is of semiconductor material, such as polysilicon doped to have the second conductivity type, here of P-type, for example it is doped with boron.

The TFT gate region 45 may have a thickness comprised between 50 nm and 150 nm, for example of 100 nm.

In this manner, the semiconductor region 39, the gate dielectric region 44 and the TFT gate region 45 form a TFT stack 47 that may have a very small overall thickness, for example of 300 nm.

A second sealing region 46, for example of silicon nitride, extends on the gate dielectric region 44, on lateral surfaces and on a top surface of the TFT gate region 45.

The second sealing region 46 may have a thickness comprised between 20 nm and 100 nm, for example of 45 nm.

In practice, the passivation layer 30 forms, with the first sealing region 25 (in the first device portion 11) and with the second sealing region 46 (in the second device portion 12), an insulating layer that surrounds the HEMT gate region 24 and the TFT gate region 45.

A TFT source contact region 48, a TFT drain contact region 49 and a TFT gate contact region 50 extend in contact, respectively, with the TFT source region 40, the TFT drain region 41 and the TFT gate region 45.

The TFT source contact region 48 and the TFT drain contact region 49 extend through the gate dielectric region 44 and the second sealing region 46 and, in part, above the latter; the TFT gate contact region 50 extends through and, in part, above the second sealing region 46.

TFT source contact 48, TFT drain contact 49, and TFT gate contact 50 regions may have a thickness comprised between 50 nm and 400 nm, for example of 200 nm or 250 nm.

Vias 53 extend through the passivation layer 30 from the top surface 30A thereof to the HEMT gate contact region 35, the HEMT drain contact region 28, the HEMT source contact region 27, the field-plate region 36, the TFT source contact region 48, the TFT drain contact region 49, and the TFT gate contact region 50.

Metal contact regions or plug regions 54 extend in the vias 53 and first-level metal regions 55 extend above the top surface 30A of the passivation layer 30, in direct electrical contact with the plug regions 54. The first-level metal regions 55 may be of the same material (e.g., of tungsten W) and be formed in the same deposition step as the plug regions 54, as described below, or may be formed in two different steps and of different material (e.g., and typically, copper or aluminum).

The plug regions 54 are also identified (where necessary) as HEMT source and drain plug regions 54A; HEMT gate plug region 54B; field-plate plug region 54C; TFT source and drain plug regions 54D and TFT gate plug region 54E.

In the integrated electronic device 1, therefore, the HEMT 11 and the TFT 13 are both integrated on the GaN-based layers 21, 22 and their conduction regions (as well as the field plate 36) have a comparable height, with respect to the top surface 2A of the body 2, allowing for the formation of vias 53 and metal contact regions 54 having heights comparable to each other and such as not to create technological difficulties, avoiding for example the risk of over-etchings, typical for shallower vias in case of opening vias having very different heights.

For instance, in the case of layers having the exemplary thicknesses indicated above, the following heights are obtained with respect to the top surface 2A of the body 2.

The top surface of the HEMT gate contact region 35 is at an approximate height of about 0.5 μm, given by the sum of the following thicknesses: 100 nm (HEMT gate region 24)+40 nm (first sealing region 25)+150 nm (second dielectric layer 32)+200 nm (HEMT gate contact region 35).

The top surface of the highest portion of the field-plate region 36 is at an approximate height of about 0.24 μm, given by the sum of the following thicknesses: 40 nm (first sealing region 25)+45 nm (thin portion 26A of the ohmic dielectric layer 26)+70 nm (first dielectric layer 31)+85 nm (field-plate region 36).

The top surfaces of the HEMT source and drain contact regions 27, 28 are at an approximate height of about 0.25 μm, given by the sum of the following thicknesses: 45 nm (thin portion 26A of the ohmic dielectric layer 26)+200 nm (HEMT source and drain contact regions 27, 28); and
the top surface of the TFT gate contact region 50 is at an approximate height of about 0.7 μm, given by the sum: 70 nm (thick portion 26B of the ohmic dielectric layer 26)+50 nm (basement insulation region 38) +100 nm (semiconductor region 39)+100 nm (gate dielectric region 44)+100 nm (TFT gate region 45)+70 nm (second sealing region 46)+200 nm (TFT gate contact region 50).

The height difference between the lowest structure (field-plate region 36) and the highest structure (TFT gate contact region 50), and consequently the depth difference between the field-plate plug region 54C and the TFT gate plug region 54E is therefore only about 0.46 μm, relatively negligible compared to the height of the vias 53, comprised between 700 and 1100 nm.

Consequently, the etching step of the vias 53 (described below) does not entail particular risks of over-etching of the contact regions 48-50 of the TFT 13.

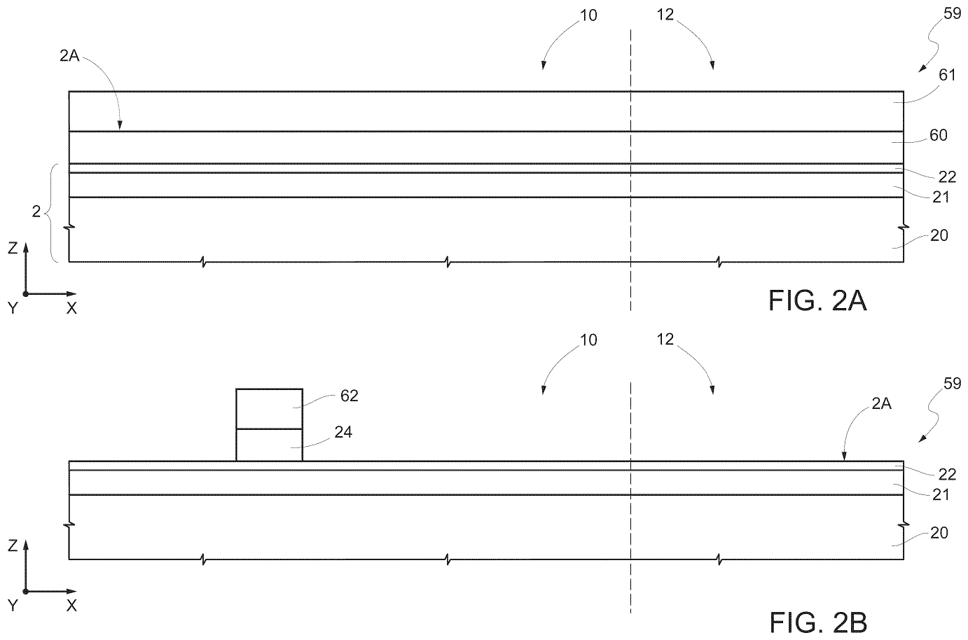

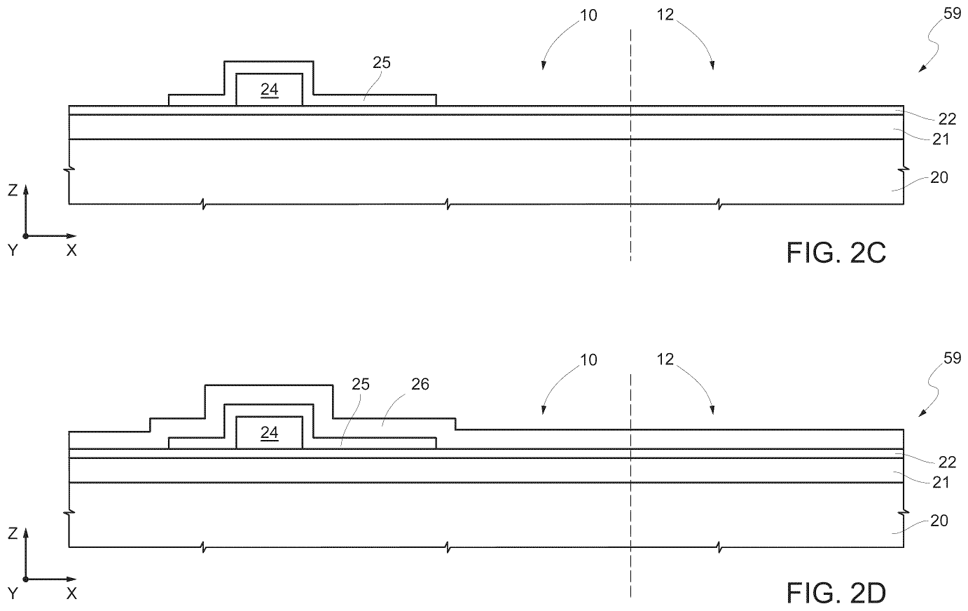

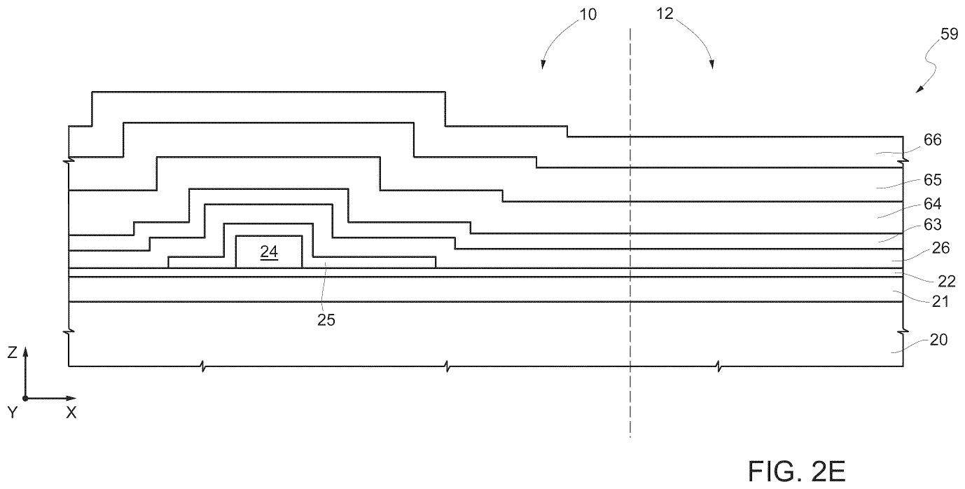

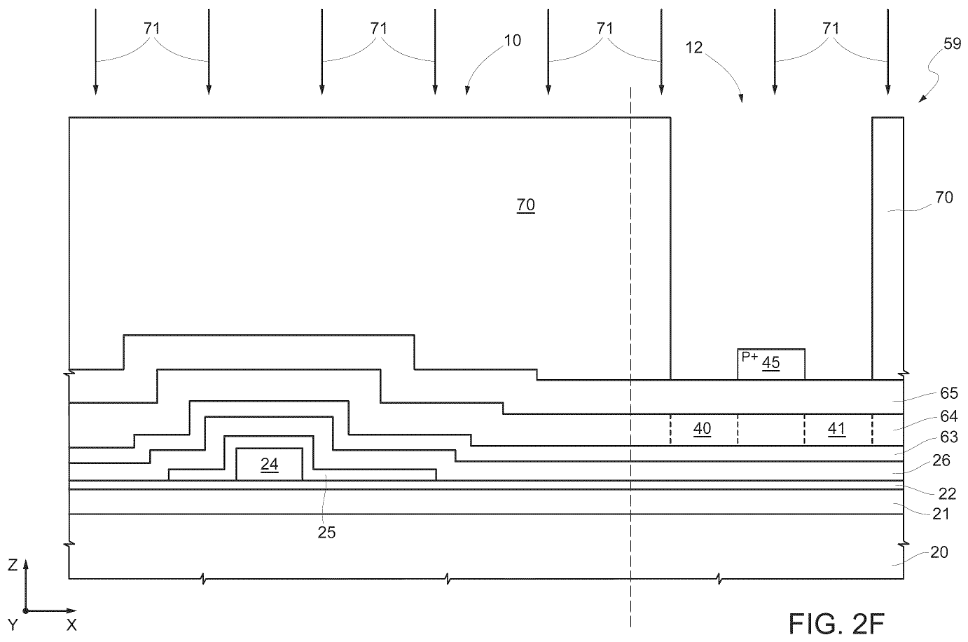

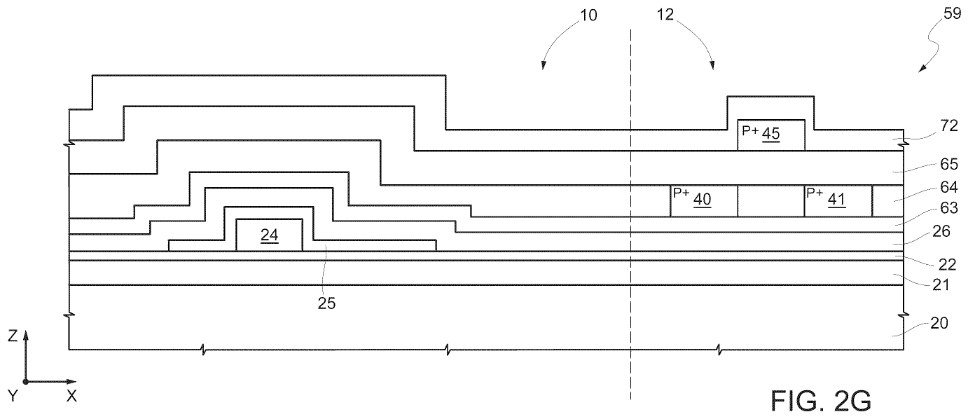

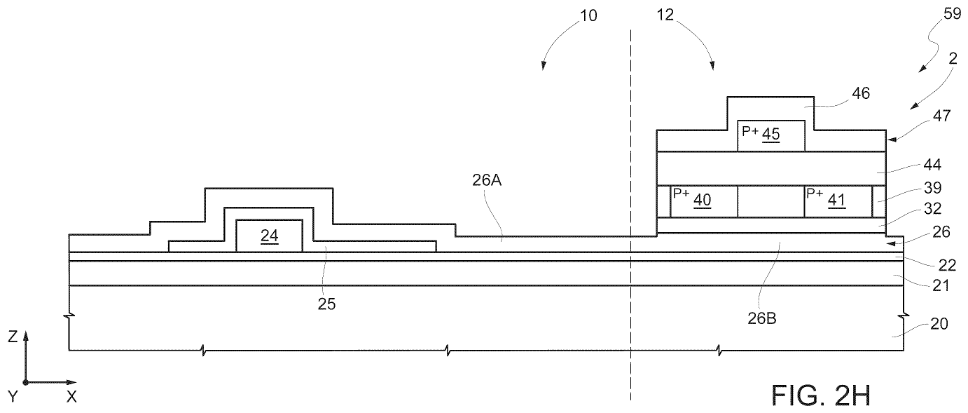

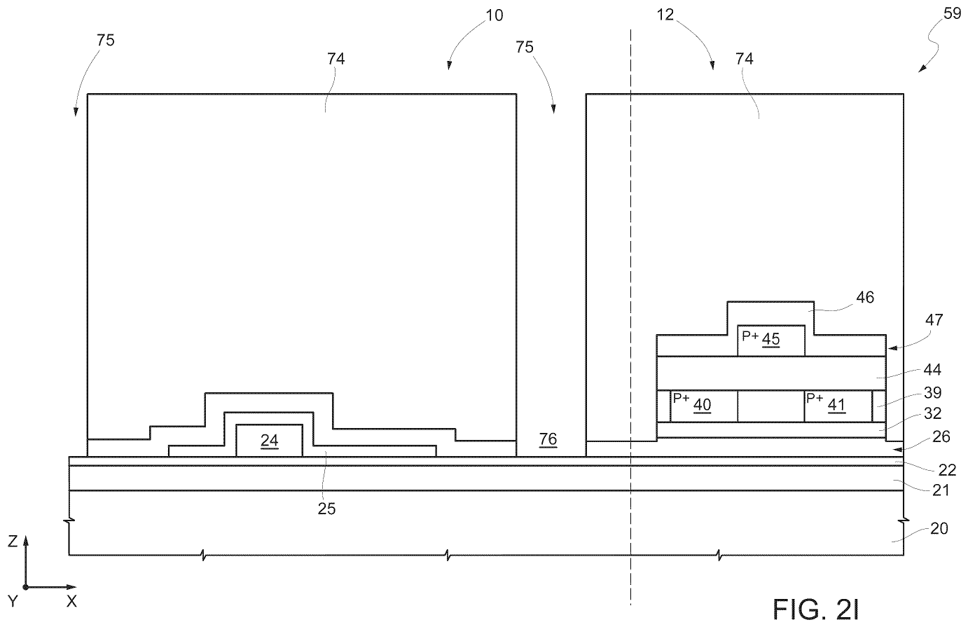

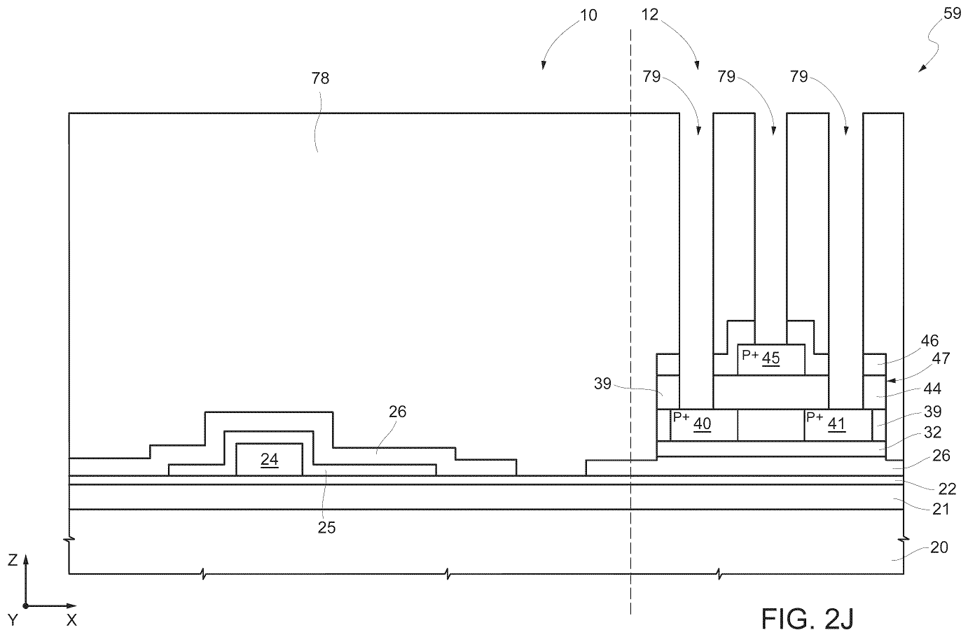

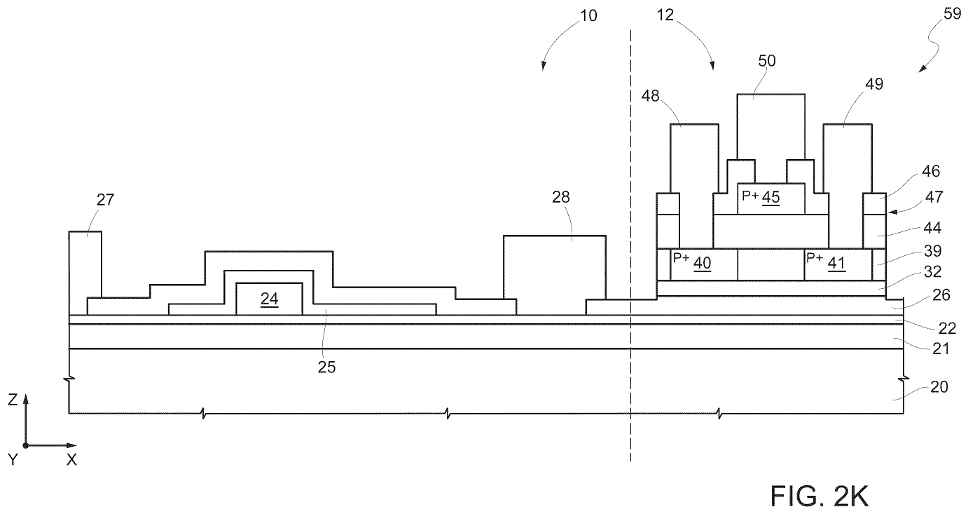

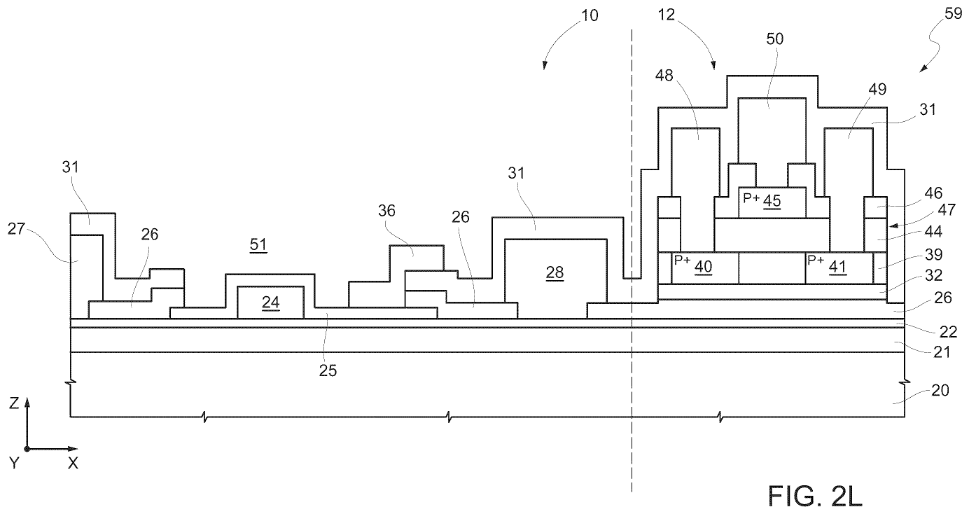

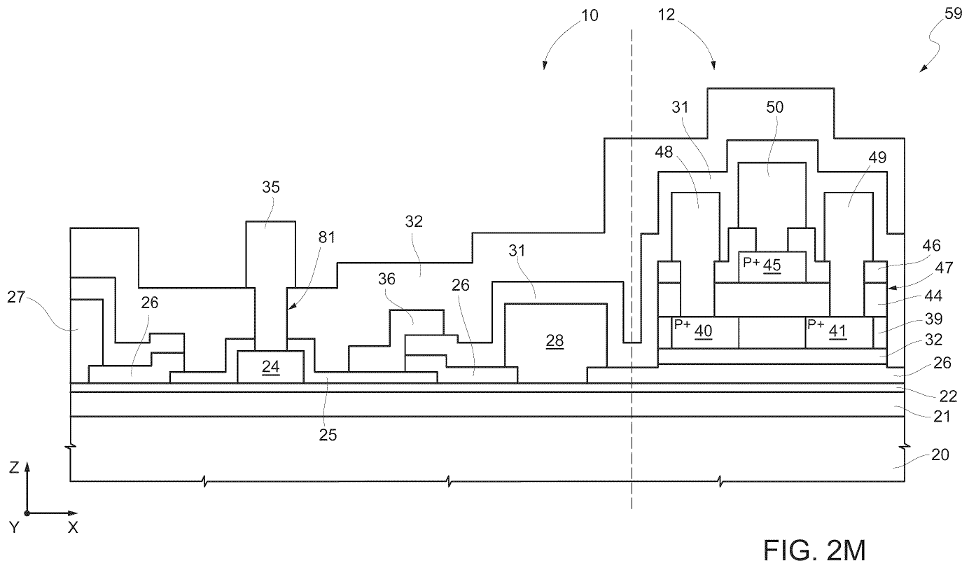

The integrated electronic device 1 of FIG. 1 may be formed as described hereinbelow with reference to FIGS. 2A-2M.

FIG. 2A shows a wafer 59 wherein it is desired to form the integrated electronic device 1.

FIG. 2A shows an initial stage, with the wafer 59 comprising the portion intended to form the semiconductor body 2 and therefore identified by this number. In FIG. 2A, only the first semiconductor layer 21 and the second semiconductor layer 22 of the semiconductor body 2 are shown (the substrate 20 is not shown). A gate layer 60, intended to form the HEMT gate region 24 and therefore of semiconductor material and thickness as previously described, is already present on the top surface 2A of the semiconductor body 2.

A masking layer 61 for example of silicon oxide extends on the gate layer 60.

In FIG. 2A, the areas intended to form the first device portion 10 and the second device portion 12 are also already identified by the reference numbers 10 and 12.

In FIG. 2B, the masking layer 61 is defined so as to form a hard mask 62 in the first device portion 10 and, using the hard mask 62, the gate layer 60 is etched, forming the HEMT gate region 24.

After removal of the hard mask 62, FIG. 2C, a first sealing layer, in the example indicated above of silicon oxide, is deposited and defined, forming the first sealing region 25.

In FIG. 2D, the ohmic dielectric layer 26 is deposited on the first sealing region 25 and the top surface 2A of the semiconductor body 2, where exposed. The ohmic dielectric layer 26, in the example of silicon nitride, initially has approximately uniform thickness on the entire wafer 59, for example 70 nm, as indicated above.

In FIG. 2E, a stack of layers is deposited including a basement insulation layer 63, an undoped semiconductor layer 64, a gate dielectric layer 65 and a doped polycrystalline silicon layer 66, intended to form, respectively, the basement insulation region 38, the semiconductor region 39, the gate dielectric region 44 and the TFT gate region 45 of FIG. 1. The layers 63-66 are therefore materials and have the thicknesses indicated above for the relative regions.

Then, in a manner not shown, the doped polycrystalline silicon layer 66 is defined, using a TFT gate definition mask not shown that covers only the area of the wafer 59 where it is desired to form the TFT gate region 45 and removes elsewhere the doped polycrystalline silicon layer 66.

Successively, the first and the second current conduction regions 40, 41 are implanted. To this end, as shown in FIG. 2F, an S/D implant mask 70 is used that completely covers the first device portion 10 and leaves uncovered, in the second device portion 12, only the TFT gate region 45 and portions, of the gate dielectric layer 65, adjacent to the same TFT gate region 45. For example, a boron implant is performed that has a dose comprised between 10¹⁴ and 2*10¹⁵ atoms/cm² and is indicated in FIG. 2F by arrows 71. Implant 71 passes through the gate dielectric layer 65, determines a charge accumulation in the portions of the undoped semiconductor layer 64 where it is desired to form the current conduction regions 40, 41 (therefore indicated by a dashed line) and also increases the doping level of the TFT gate region 45.

After removal of the S/D implant mask 70, FIG. 2G, a rapid annealing is performed in an RTA (Rapid Temperature Annealing) furnace, for example at 800-900° C., activating the implanted ions and forming the current conduction regions 40, 41, and a second sealing layer 72 is deposited, for example of silicon nitride SiN, intended to form the second sealing region 46 and having the thickness previously described.

By using a specific mask not shown and a multi-step etching process, the stack formed by the second sealing layer 72, the gate dielectric layer 65, the undoped semiconductor layer 64 and the basement insulation layer 63 is defined. Thus, FIG. 2H, the basement insulation region 38, the semiconductor region 39, the gate dielectric region 44 (forming the TFT stack 47) and the second sealing region 46 are formed. The stack of layers 72, 65, 64 and 63 is instead completely removed from the first device portion 10.

In this step, the exposed portion of the ohmic dielectric layer 26 is superficially etched, so that it has the original thickness in the thick portion 26B, below the TFT stack 47, in the second device portion 12, and a lower thickness elsewhere, in the first device portion 10 and alongside the TFT stack 47, forming the thin portion 26A.

In FIG. 2I, opening of the source and drain contacts of the HEMT 11 is performed. To this end, wafer 59 is covered by a HEMT contact masking layer 74, for example of resist, except at the S/D windows 75 where it is desired to form the HEMT source contact region 27 and the HEMT drain contact region 28. Then, the ohmic dielectric layer 26 is locally etched, on the two sides of the first sealing region 25, in the first device portion 10, forming S/D contact openings 76 that reach the second semiconductor layer 22 or may extend partially or completely also in the latter.

In FIG. 2J, opening of the source, gate and drain contacts of the TFT 13 is performed. To this end, after a possible removal of the HEMT contact masking layer 74 of FIG. 2I, the wafer 59 is covered by a TFT contact masking layer 78, for example of resist, except at the HEMT contact windows 79 where it is desired to form the contact regions 48-50 of the TFT 13.

Then the second sealing region 46 and the gate dielectric region 44 (alongside the TFT gate region 45), in the stack 47, are locally etched, forming TFT contact openings 80 that reach the first and the second current conduction regions 40, 41 (for the source and drain contacts 48, 49 of the TFT 13) and the TFT gate region 45 (for the gate contact 50 of the TFT 13).

In FIG. 2K, after removal of the TFT contact masking layer 78, the contact regions 27, 28 and 48-50 are simultaneously formed, for example by a single deposition of a metal layer that fills the S/D contact openings 76 and the TFT contact openings 80 and definition of the contacts 27, 28 and 48-50. An annealing step in an RTA furnace follows.

In FIG. 2L, the field-plate region 36 is formed.

To this end, the first dielectric layer 31 is deposited (covering the entire surface of the wafer 59 and surrounding, in particular, all the contact regions 27, 28, 48-50); then the first dielectric layer 31 and the ohmic dielectric layer 26 (in the example considered, of the same material, silicon nitride SiN) are selectively removed, above the first sealing region 25, forming a HEMT opening 51. Then a conductive material layer is deposited and defined to form the field-plate region 36 which extends, as mentioned above, partly on the first sealing region 25 and partly on the first dielectric layer 31.

In FIG. 2M, the HEMT gate contact region 35 is formed.

To this end, the second dielectric layer 32 is deposited and is opened (together with the first sealing region 25), by etching, above the HEMT gate region 24, forming a HEMT gate opening 81. Then a gate metal layer is deposited and defined, thereby forming the HEMT gate contact region 35.

Subsequently, the third dielectric layer 33 is deposited, the vias 53 are formed, a first-level metal layer (metal 1) is deposited and defined, forming the first-level metal regions 55 of FIG. 1.

Usual front-end processing steps follow, for the possible formation of further metal levels, interconnections, passivations, pad formation and singulation, in a manner known per se and not shown.

The integrated electronic device 1 of FIG. 1 is thereby obtained, where the structures above the first metal level are not represented.

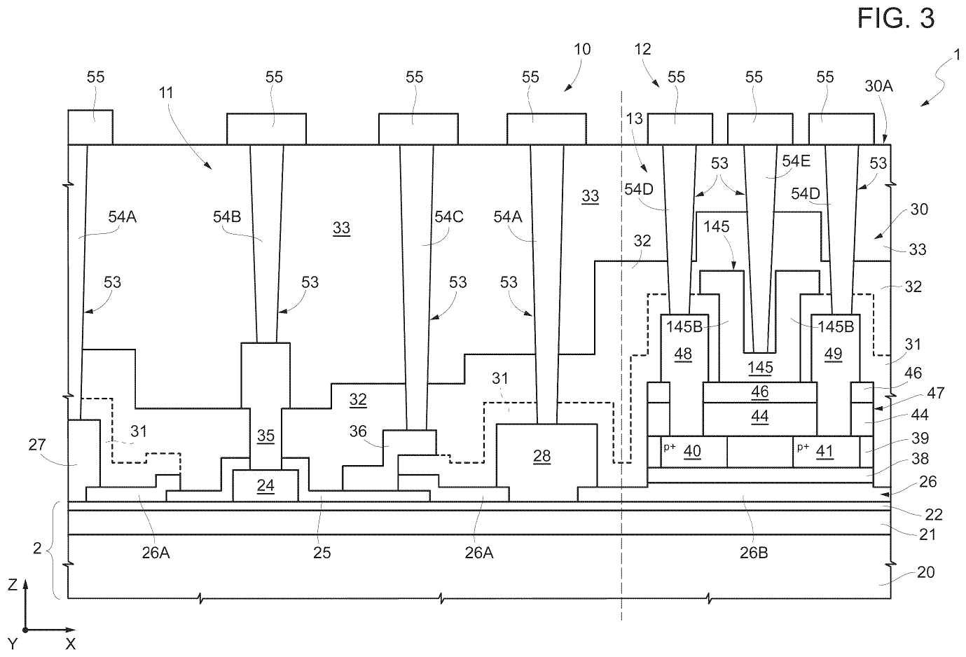

FIG. 3 shows a variant of the present integrated electronic device, indicated by 100, wherein the thin-film transistor is of the metal-gate type, while the heterostructure transistor has the same structure as in FIG. 1.

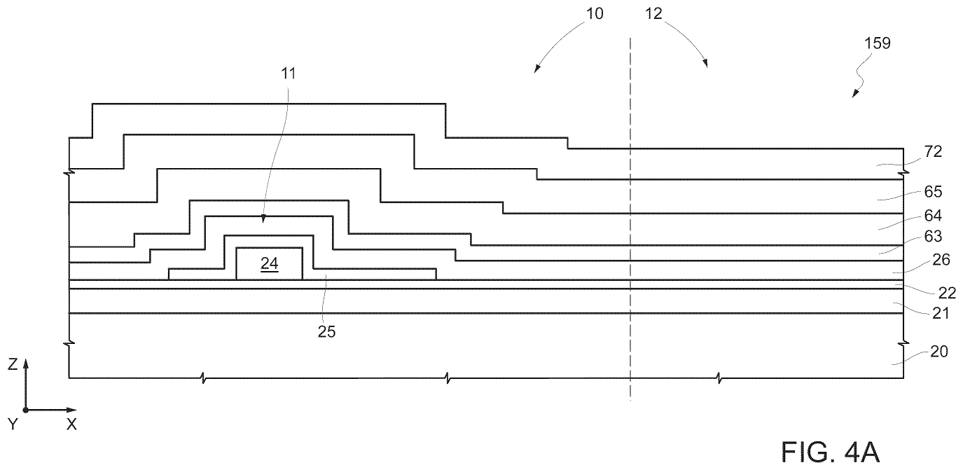

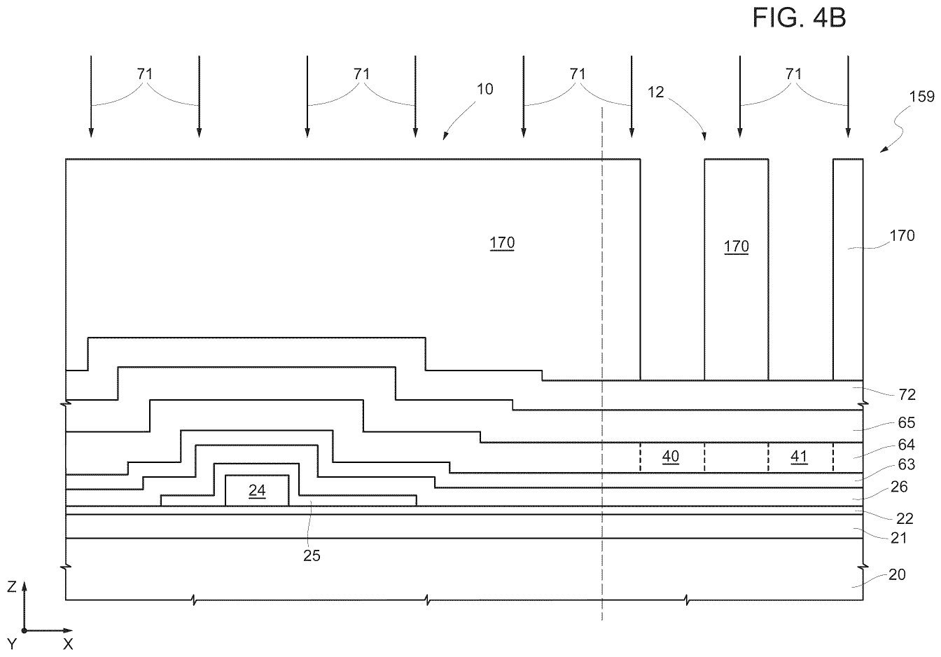

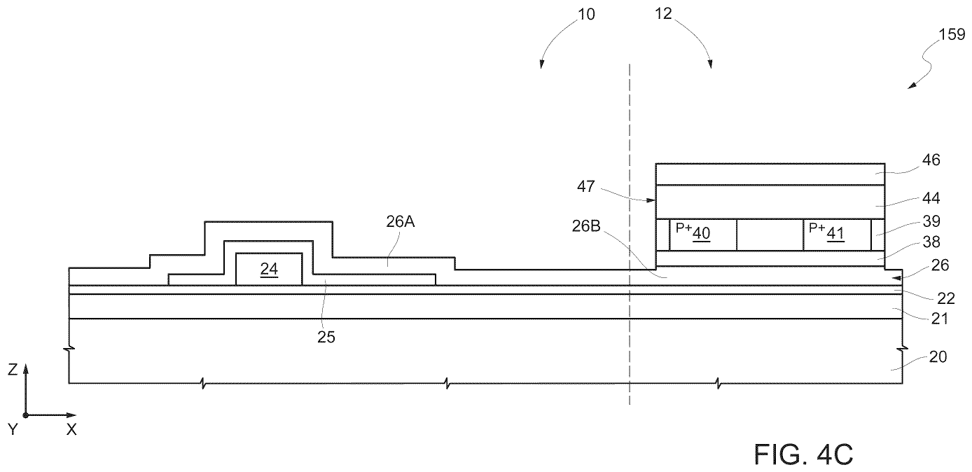

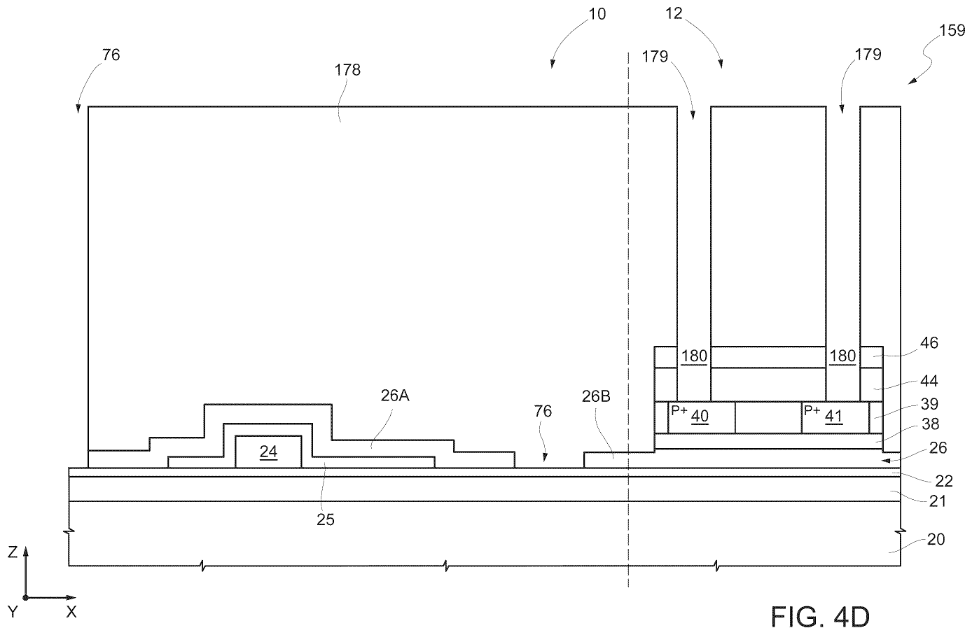

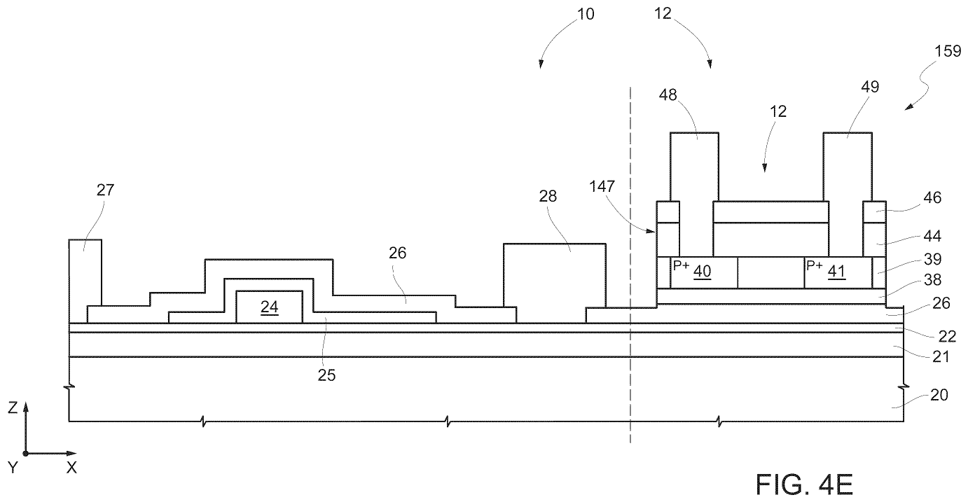

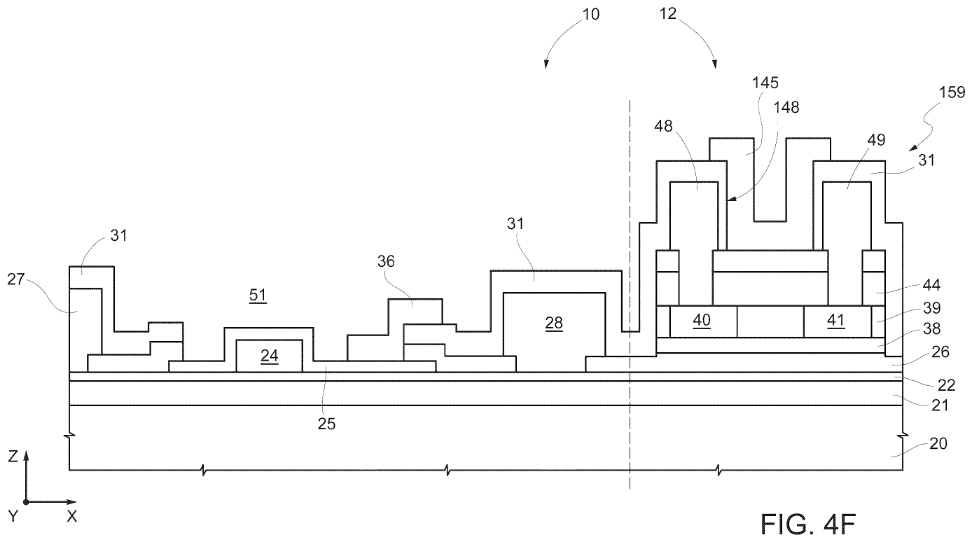

In FIG. 3 therefore (and in FIGS. 4A-4F which show the relative manufacturing steps) the same reference numbers are used for the elements common to the integrated electronic device 1, and they are not described again, except where useful for understanding.

The integrated electronic device 100 is also divided into two portions: a first portion, again indicated by 10, accommodating the HEMT 11, and a second portion, again indicated by 12, accommodating a metal-gate thin-film transistor 113, hereinafter referred to as TFT 113.

As indicated, the HEMT 11 has the same exemplary structure described with reference to FIG. 1.

TFT 113 is formed in a TFT stack 47 comprising the basement insulation region 38, the semiconductor region 39 (including the first and the second current conduction regions 40, 41) and the gate dielectric region 44.

Here, the TFT gate region (indicated by 145) comprises a metal region, for example formed by a double layer Al₂O₃/AlN. It may be formed using the same metal layer used for the field-plate region 36.

The TFT gate region 145 here is, in cross-section, approximately U-shaped and extends through the second sealing region 46 and the portion of the first dielectric layer 31 arranged above the TFT stack 47 (as well as, partially, thereabove).

In practice, the TFT gate region 145 comprises a base portion 145A (which extends above the gate dielectric region 44) and two transverse arms 145B (which extend on the walls of a TFT opening 148 of the layers 46, 31). Here, the second dielectric layer 32 extends both at the top and within the concavity of the U-shape of the TFT gate region 145, sealing the latter.

In FIG. 3, the TFT gate contact region 50 of FIG. 1 is not present; the TFT gate plug region 54E (and the relative via 53) reach the TFT gate region 145, at the base portion 145A thereof. In practice, here, the TFT gate plug region 54E is in direct contact with the TFT gate region 145.

Furthermore, also here, the passivation layer 30 forms, with the first sealing region 25 (in the first device portion 11) and with the second sealing region 46 (in the second device portion 12), an insulating layer that surrounds the HEMT gate region 24 and the TFT gate region 145.

The same dimensional considerations reported above for the integrated electronic device 1 therefore apply to the integrated electronic device 100.

The integrated electronic device 100 of FIG. 3 may be manufactured as described hereinbelow with reference to FIGS. 4A-4F.

Initially, the manufacturing process comprises steps similar to those described above with reference to FIGS. 2A-2D, for forming the HEMT 11 (comprising the definition of the HEMT gate region 24, forming the first sealing region 25 and depositing the ohmic dielectric layer 26).

Then, FIG. 4A, the stack of layers 63-65, on the wafer, here indicated by 159, is deposited.

Here, unlike FIG. 2E, the doped polycrystalline silicon layer 66 is not deposited, but the second sealing layer 72 is deposited immediately.

Then, FIG. 4B, the first and the second current conduction regions 40, 41 are implanted. To this end, an S/D implant mask 170 is used which completely covers the first device portion 10 and, in the second device portion 12, covers a channel area 171 in the undoped semiconductor layer 64. For example, a boron implant with a dose of 10¹⁵ atoms/cm² is performed, indicated in FIG. 4B by the arrows 71, which here passes through both the second sealing layer 72 and the gate dielectric layer 65 and determines an accumulation of charges in the portions of the undoped polycrystalline silicon layer 64 where it is desired to form the current conduction regions 40, 41 (therefore indicated by a dashed line).

After removal of the S/D implant mask 170, a rapid annealing is performed in an RTA (Rapid Temperature Annealing) furnace, for example at 800-900° C., activating the implanted ions and forming the current conduction regions 40, 41, FIG. 4C.

Furthermore, using a specific mask not shown and a multi-step etching process, the stack formed by the second sealing layer 72, the gate dielectric layer 65, the undoped semiconductor layer 62 and the basement insulation layer 63 is defined. Then, FIG. 4C, the basement insulation region 38, the semiconductor region 39, the gate dielectric region 44 (forming the TFT stack 47) and the second sealing region (again indicated by 46, although with a different shape with respect to FIG. 2H) are formed. The stack of layers 72, 65, 64 and 63 is instead completely removed from the first device portion 10.

In this step, similarly to FIG. 2H, the exposed portion of the ohmic dielectric layer 26 is superficially removed, forming the thick portion 26B and the thin portion 26A. Subsequently, in a manner not shown and similarly to what has been described with reference to FIG. 2J, the source and drain contacts of the TFT 13 are opened, forming the S/D contact openings 76 (FIG. 4D).

In FIG. 4D, only the source and drain contacts of the TFT 113 are opened. To this end, the wafer 159 is covered by a TFT contact masking layer 178, for example of resist, except at the HEMT contact windows 179 where it is desired to form the contact regions 48 and 49 of the TFT 13. Then the second sealing region 46 and the gate dielectric region 44, in the stack 47, are locally etched, forming TFT contact openings 180 that reach the first and the second current conduction regions 40, 41.

In FIG. 4E, after removal of the TFT contact masking layer 178, the contact regions 27, 28, 48 and 49 are formed, similarly to what described with reference to FIG. 2K.

In FIG. 4F, the first dielectric layer 31 is deposited, covers the entire surface of the wafer 159 and surrounds, in particular, all the contact regions 27, 28, 48 and 49.

Then the first dielectric layer 31 and the ohmic dielectric layer 26 are selectively removed, above the HEMT gate region 24, the first sealing region 25 (here forming the HEMT opening 51) and a portion (e.g., the central portion) of the gate dielectric region 44 (here forming the TFT opening 148).

Then the field-plate region 36 in the first device portion 10 and the TFT gate region 145 in the second device portion 12 are formed simultaneously, e.g. by deposition and definition of one or more layers of conductive material.

Subsequently, similarly to what described with reference to FIG. 2M, the second dielectric layer 32 is deposited; layer 32 is opened (together with the first sealing region 25) above the HEMT gate region 24; a gate metal layer is deposited and defined, forming the HEMT gate contact region 35; the third dielectric layer 33 is deposited; and the vias 53 are formed. In this case, as indicated above, the via 53 to the TFT gate region 145 is deeper and reaches the base portion 145A of the latter.

Then, as indicated above, a first-level metal layer (metal 1) is deposited and defined, forming the first-level metal regions 55, obtaining the structure shown in FIG. 3.

The usual front-end processing steps follow, for forming further metal levels, interconnections, passivations, pads and the singulation, in a manner known per se and not shown.

In this manner, an integrated electronic device 1, 100 based on GaN technology and a thin logic transistor, for example an (N-channel or P-channel) complementary transistor, may be formed, on the same GAN-based layer, with comparable structure heights. This allows all the contact regions 27, 28 and 48, 49 and possibly 50 to be formed simultaneously by a single etching step and a single metal deposition. In this step, it is advantageous that etching of the passivation layer 30 is well controllable, without risks of over-etching that would cause thickness reductions of the underlying regions and resulting uncontrolled non-ideal electrical characteristics.

The reduced height difference of the active structures (HEMT 11 and TFT 13; 113) means that the integrated electronic device has small dimensions compared to integration solutions wherein the GaN components and the TFT components are formed one on top of the other or on different superimposed substrates.

Furthermore, the manufacturing process has reduced costs compared to the manufacture of devices formed separately or by removing thick substrate layers, by using the same layers, sometimes defined in a same step both in the first device portion 10 and in the second device portion 12.

For instance, in the integrated electronic device of FIG. 3, the gate region 145 may be advantageously formed in the same manufacturing step as the field-plate region 36; the contact regions 27, 28,48-50 may be formed simultaneously; the vias 53 and the plug regions 54 may be formed simultaneously in both device portions 10, 12.

Finally, it is clear that modifications and variations may be made to the integrated electronic device and to the manufacturing process described and illustrated here without thereby departing from the scope of the present disclosure, as defined in the attached claims.

For example, the TFT might be of a different type with respect to the two solutions described.

Furthermore, the formation sequence of the contact regions 27, 28, 48, 49 and possibly 50 may vary from what has been described; for example, the TFT contact regions 48-50 may be formed separately from the HEMT contact regions 27 and 28. Furthermore, the TFT contact regions 48-50 may be formed prior to defining the TFT stack.

The present description may be exemplified as follows:
Example 1. An integrated electronic device (1; 100), comprising a heterostructure field-effect transistor-HEMT-(11) and a MOSFET transistor (13) and including:
a body (2) having a heterostructure comprising at least one gallium nitride-GaN-based layer (21, 22);
a first gate region (24) overlying the at least one GaN-based layer (21, 22);
a TFT region stack (47; 147) on the at least one GaN-based layer (21, 22), laterally to the first gate region (24), the TFT region stack including a basement insulation region (38) overlying the at least one GaN-based layer (21, 22), a semiconductor region (39) overlying the basement insulation region (38), and a gate dielectric region (44) overlying the semiconductor layer (39);
a second gate region (45; 145) overlying the gate dielectric region (44);
an insulating layer (25, 26, 30, 46) surrounding at least at the top and laterally the first gate region (24), the second gate region (45; 145), and the TFT region stack (47; 147) as well as covering the at least one GaN-based layer (21, 22) laterally to the first gate region (24) and the TFT region stack (47; 147); and
a plurality of plug metal regions (54A-54E) extending through the insulating layer and in electrical contact with the first gate region (24), the second gate region (45; 145), the at least one GaN-based layer (21, 22), and the semiconductor layer (39).

Example 2. The device according to the preceding example, wherein the MOSFET transistor (13) is a thin-film transistor-TFT-and wherein the semiconductor region (39) accommodates a first and a second current conduction region (40, 41) separated by a channel portion (42) of the semiconductor region (39), the channel portion (42) underlying the second gate region (45; 145).

Example 3. The device according to the preceding example, wherein the second gate region (45) comprises a doped semiconductor region.

Example 4. The device according to example 2, wherein the second gate region (145) comprises a metal region.

Example 5. The device according to any of examples 2-4, further comprising a first HEMT conduction contact region (28), of metal, on the at least one GaN-based layer (21, 22); a second HEMT conduction contact region (27), of metal, on the at least one GaN-based layer (21, 22), the first HEMT conduction contact region (28) and the second HEMT conduction contact region (27) arranged on opposite sides of the first gate region (24); a HEMT gate contact region (35), of metal, in contact with the first gate region (24); a first TFT conduction contact region (49), of metal, in contact with a first current conduction region (40); a second TFT conduction contact region (48), of metal, in contact with a second current conduction region (41), the first TFT conduction contact region (48) and the second TFT conduction contact region (49) arranged on opposite sides of the second gate region (45; 145),
the first HEMT conduction contact region (28), the second HEMT conduction contact region (27), the HEMT gate contact region (35), the first TFT conduction contact region (48), and the second TFT conduction contact region (48) being formed in a same metal layer and being in direct electrical contact with a respective plug metal region of the plurality of metal contact regions (54A-54D).

Example 6. The device according to the preceding example, when depending on example 3, further comprising a TFT gate contact region (50), of metal, superimposed on the second gate region (45) and in direct electrical contact with a respective plug metal region (54E) of the plurality of plug metal regions (54A-54E).

Example 7. The device according to any of the preceding examples, further comprising a field-plate region (36), of electrically conductive material, arranged laterally to the first gate region (24).

Example 8. The device according to the preceding example when depending on example 4, wherein the field-plate region (36) is of the same metal as the metal region of the second gate region (145).

Example 9. A process for manufacturing an integrated electronic device, comprising:
forming a body (2) having a heterostructure in at least one gallium nitride-GaN-based layer (21, 22);
forming a first gate region (24) overlying the at least one GaN-based layer 21, 22;
forming a TFT region stack (47; 147) on the at least one GaN-based layer (21, 22), laterally to the first gate region (24), the TFT region stack including a basement insulation region (38) overlying the at least one GaN-based layer (21, 22), a semiconductor region (39) overlying the basement insulation region (38), and a gate dielectric region (44) overlying the semiconductor region (39);
forming a second gate region (45; 145) overlying the gate dielectric region (44);
forming an insulating layer (25, 26, 30, 46) surrounding at least at the top and laterally the first gate region (24), the second gate region (45; 145), and the TFT region stack (47; 147) as well as covering the at least one GaN-based layer (21, 22) laterally to the first gate region (24) and the TFT region stack (45; 145); and
forming a plurality of plug metal regions (54A-54E) extending through the insulating layer and in electrical contact with the first gate region (24), the second gate region (45; 145), the at least one GaN-based layer (21, 22), and the semiconductor layer (39).

Example 10. The process according to the preceding example, wherein the MOSFET transistor (13) is a thin-film transistor-TFT-, wherein forming a TFT region stack (47; 147) comprises forming a first and a second current conduction region (40, 41), separated by a channel portion (42) of the semiconductor region (39), underlying the second gate region (45; 145).

Example 11. The process according to the preceding example, wherein forming a TFT region stack (47) comprises:
forming a stack of layers including a basement insulation layer (63), a first semiconductor layer (64), and a gate dielectric layer (65); and
defining the stack of layers,
wherein, prior to defining the stack of layers, there are performed the steps of:
   forming and defining a second semiconductor layer (66) above the gate dielectric layer (65) to form the second gate region (45);
introducing doping ion species in the first semiconductor layer (64) to form the first and the second current conduction regions (40, 41); and
forming a TFT sealing layer (46),
wherein defining the stack of layers comprises defining the TFT sealing layer (46).

Example 12. The process according to the preceding example, further comprising, prior to forming a plurality of plug metal regions (54A-54E), simultaneously forming a plurality of contact regions, of metal, including a first and a second HEMT conduction contact region (27, 28), on the at least one GaN-based layer (21, 22), the first HEMT conduction contact region (27) and the second HEMT conduction contact region (28) being arranged on opposite sides of the first gate region (24); a HEMT gate contact region (35), in contact with the first gate region (24); a first and a second TFT conduction contact region (48, 49), in contact with the first and, respectively, the second current conduction region (40, 41), the first TFT conduction contact region (48) and the second TFT conduction contact region (49) being arranged on opposite sides of the second gate region (45; 145); and a TFT gate contact region (50), in contact with the second gate region (45), wherein the contact regions are in direct electrical contact with a respective plug metal region of the plurality of plug metal regions (54A-54E).

Example 13. The process according to example 10, wherein forming a TFT region stack (147) comprises:
forming a stack of layers including a basement insulation layer (63), a first semiconductor layer (64), a gate dielectric layer (65), and a TFT sealing layer (72);
selectively introducing doping ion species in the first semiconductor layer (64) to form the first and the second current conduction regions (40, 41); and
defining the stack of layers, forming the basement insulation region (38), the semiconductor region (39), the gate dielectric region (44), and a TFT sealing region (46);
the process further comprising, after the step of defining the stack of layers, forming and defining a gate metal layer above the gate dielectric region (44) to form the second gate region (145).

Example 14. The process according to the preceding example, comprising, prior to forming a stack of layers, forming a HEMT sealing region (25), surrounding the first gate region (24); wherein forming and defining a gate metal layer further comprises forming a field-plate region (36) overlying the HEMT sealing region and arranged laterally to the first gate region (24).

Example 15. The process according to example 13 or 14, comprising, prior to forming the second gate region 145, simultaneously forming a plurality of contact regions, of metal, including a first and a second TFT conduction contact 48, 49 in direct electrical contact with the first and the second current conduction regions 40, 41; a first and a second HEMT conduction contact 27, 28 in contact with the at least one GaN-based layer; and a HEMT gate contact region 35 in contact with the first gate region 24; wherein the contact regions are in direct electrical contact with a respective plug metal region of the plurality of plug metal regions (54A-54D) and the second gate region (145) is in direct electrical contact with a respective plug metal region (54E) of the plurality of plug metal regions (54A-54E).

1. An integrated electronic device, comprising a heterostructure field-effect transistor (HEMT) and a MOSFET transistor and including:
a body having a heterostructure comprising at least one gallium nitride based layer;
a first gate region overlying the at least one gallium nitride based layer;
a TFT region stack on the at least one gallium nitride based layer, laterally to the first gate region, the TFT region stack including a basement insulation region overlying the at least one gallium nitride based layer, a semiconductor region overlying the basement insulation region, and a gate dielectric region overlying the semiconductor region;
a second gate region overlying the gate dielectric region;
an insulating layer surrounding, at least at a top and laterally, the first gate region, the second gate region, and the TFT region stack as well as covering the at least one gallium nitride based layer laterally to the first gate region and the TFT region stack; and
a plurality of plug metal regions extending through the insulating layer and in electrical contact with the first gate region, the second gate region, the at least one gallium nitride based layer, and the semiconductor region.

2. The integrated electronic device of claim 1, wherein the MOSFET transistor is a thin-film transistor (TFT) and wherein the semiconductor region accommodates a first and a second current conduction region separated by a channel portion of the semiconductor region, the channel portion underlying the second gate region.

3. The integrated electronic device of claim 1, wherein the second gate region comprises a doped semiconductor region.

4. The integrated electronic device of claim 2, wherein the second gate region comprises a metal region.

5. The integrated electronic device of claim 2, further comprising a first HEMT conduction contact region, of metal, on the at least one gallium nitride based layer; a second HEMT conduction contact region, of metal, on the at least one gallium nitride based layer, the first HEMT conduction contact region and the second HEMT conduction contact region arranged on opposite sides of the first gate region; a HEMT gate contact region, of metal, in contact with the first gate region; a first TFT conduction contact region, of metal, in contact with a first current conduction region; a second TFT conduction contact region, of metal, in contact with a second current conduction region, the first TFT conduction contact region and the second TFT conduction contact region arranged on opposite sides of the second gate region,
the first HEMT conduction contact region, the second HEMT conduction contact region, the HEMT gate contact region, the first TFT conduction contact region, and the second TFT conduction contact region being formed in a same metal layer and being in direct electrical contact with a respective plug metal region of the plurality of plug metal regions.

6. The integrated electronic device of claim 3, further comprising a TFT gate contact region, of metal, superimposed on the second gate region and in direct electrical contact with a respective plug metal region of the plurality of plug metal regions.

7. The integrated electronic device of claim 1, further comprising a field-plate region, of electrically conductive material, arranged laterally to the first gate region.

8. The integrated electronic device of claim 7, wherein the field-plate region is of a same metal as a metal region of the second gate region.

9. A process for manufacturing an integrated electronic device comprising a heterostructure field-effect transistor and a MOSFET transistor, the process comprising:
forming a body having a heterostructure in at least one gallium nitride based layer;
forming a first gate region overlying the at least one gallium nitride based layer;
forming a TFT region stack on the at least one gallium nitride based layer, laterally to the first gate region, the TFT region stack including a basement insulation region overlying the at least one gallium nitride based layer, a semiconductor region overlying the basement insulation region, and a gate dielectric region overlying the semiconductor region;
forming a second gate region overlying the gate dielectric region;
forming an insulating layer surrounding, at least at a top and laterally, the first gate region, the second gate region, and the TFT region stack as well as covering the at least one gallium nitride based layer laterally to the first gate region and the TFT region stack; and
forming a plurality of plug metal regions extending through the insulating layer and in electrical contact with the first gate region, the second gate region, the at least one gallium nitride based layer, and the semiconductor region.

10. The process of claim 9, wherein the MOSFET transistor is a thin-film transistor (TFT), wherein forming a TFT region stack comprises forming a first and a second current conduction region, separated by a channel portion of the semiconductor region, underlying the second gate region.
